(19) United States
(12) Patent Application Publication
(10) Pub. No.: US 2008/0135955 A1
(43) Pub. Date: Jun. 12, 2008

(54) Semiconductor device and method for fabricating the same

(76) Inventor: Hayato Korogi, Toyama (JP)

Correspondence Address: MCDERMOTT WILL & EMERY LLP, 600 13TH STREET, NW, WASHINGTON, DC, 20005-3096, US

(21) Appl. No.: 11/889,538

(22) Filed: Aug. 14, 2007

(30) Foreign Application Priority Data
Dec. 8, 2006 (JP) 2006-331909

(51) Int. Cl. H01L 29/94; H01L 21/336

(52) U.S. Cl. 257/412; 438/308; 257/E29.345; 257/E21.409

(57) ABSTRACT

A semiconductor device includes low concentration source/drain regions and high concentration source/drain regions each being formed in a semiconductor substrate, a gate insulation film formed on part of the semiconductor substrate located between the low concentration source/drain regions when viewed from the top and a gate electrode formed of metal silicide on the gate insulation film. A gate length of upper part of the gate electrode is larger than a gate length of other part of the gate electrode.

### BACKGROUND OF THE INVENTION

1. Field of the Invention

The present invention relates to a semiconductor device including a gate electrode with a silicide layer and a method for fabricating the semiconductor device.

2. Description of the Prior Art

In recent years, as effective means for realizing increased speed of semiconductor integrated circuit devices, a method in which high-melting point metal silicide is formed on a gate electrode to reduce resistances of the electrode and a doped layer has been used. Hereafter, the known method in which a silicide layer is formed on a gate electrode will be described with reference to FIG. 5. FIG. 5 is a cross sectional view illustrating a known method for forming a silicide layer.

First, as shown in FIG. 5A, a field oxide film 2 is formed in an inert region of a silicon substrate 1 and a gate oxide film 3 having a thickness of 5-10 nm is formed in an active region of the silicon substrate 1 using respective known technologies. Next, a gate electrode 4 of, for example, polycrystalline silicon having a thickness of about 150-200 nm is formed on the gate oxide film 3 and then a silicon nitride film 5 having a thickness of about 50 nm is formed.

Next, as shown in FIG. 5B, patterning is performed using photolithography and anisotropic etching, thereby forming the gate oxide film 3, the gate electrode 4 and the silicon nitride film 5 stacked in this order from a bottom are left in a predetermined region of the silicon substrate 1. Subsequently, an oxide film (not shown) is formed over the silicon substrate 1 so as to have a thickness of about 100 nm by CVD (Chemical Vapor Deposition). Then, the oxide film is removed by anisotropic etching so that part of the oxide film is left on side surfaces of the gate oxide film 3, the gate electrode 4 and the silicon nitride film 5, thereby forming a sidewall 6 of the oxide film. Next, using the silicon nitride film 5 and the sidewall 6 as a mask, ion implantation and then heat treatment are performed, thereby forming a doped layer 7.

Next, as shown in FIG. 5C, a native oxide film (not shown) formed on the doped layer 7 is removed by buffered hydrofluoric acid and then a titanium layer 8 is formed by sputtering so as to have a thickness of about 30 nm.

Subsequently, as shown in FIG. 5D, short time heat treatment (RTA) is performed in a nitrogen atmosphere at 650° C. to 700° C. to bring the titanium layer 8 and the doped layer 7 into reaction, thereby forming a titanium silicide layer 9 having a thickness of about 50 nm on the doped layer 7. Next, remaining part of the titanium layer 8 is removed using a mixed solution of ammonia water and hydrogen peroxide solution.

Next, as shown in FIG. 5E, an interlevel insulation film 10 is formed over the silicon substrate 1 so as to have a thickness of about 500 nm. Thereafter, the interlevel insulation film 10 is flattened by performing CMP (Chemical Mechanical Polishing) until a surface of the silicon nitride film 5 is exposed. In this process step, the silicon nitride film 5 formed on the gate electrode 4 serves as CMP stopper.

Next, as shown in FIG. 5F, the silicon nitride film 5 is removed by thermal phosphoric acid. Subsequently, the native oxide film (not shown) formed on the gate electrode 4 is removed by buffered hydrofluoric acid and then a titanium layer 11 is formed over the silicon substrate 1 by sputtering so as to have a thickness of about 50 nm.

Next, as shown in FIG. 5G, short time heat treatment (RTA) is performed in a nitrogen atmosphere at 650° C.-700° C. to bring the titanium layer 11 and a polycrystalline silicon (gate electrode 4) into reaction, thereby forming a titanium silicide layer 12 having a thickness of about 80 nm on the gate electrode. Next, remaining part of the titanium layer 11 is removed by a mixed solution of ammonia water and hydrogen peroxide solution. Thereafter, short time heat treatment (RTA) is performed in a nitrogen atmosphere at 800° C. to 850° C. to reduce resistances of the titanium silicide layers 9 and 12.

Thereafter, after forming an interlevel insulation film is deposited over the silicon substrate 1 and a contact opening portion, an aluminum electrode is formed. Thus, a MOS transistor can be fabricated.

By repeating the above-described steps, the thickness of the silicide layer formed on the gate electrode can be increased, so that the resistance of the gate electrode can be further reduced (see Japanese Laid-Open Publication No. 11-121745).

### SUMMARY OF THE INVENTION

In the step (FIG. 5F) of depositing a metal film in the opening portion which reaches the gate electrode 4, if the opening portion has an increased aspect ratio with reduction in the size of semiconductor devices, a coverage failure of the metal film deposited in the opening portion easily occurs and formation of a uniform silicide layer on the gate electrode 4 becomes difficult. As a result, defective transistor characteristics, quality variations and the like might be increased.

In view of the above-described inconveniences, the present invention has been devised to provide a semiconductor device including a gate electrode which has a uniform silicide layer and of which resistance is reduced and a method for fabricating the semiconductor device.

To solve the above-described problems, a semiconductor device according to the present invention includes: a semiconductor substrate; a source region and a drain region each being formed in the semiconductor substrate; a gate insulation film formed on part of the semiconductor substrate located between the source region and the drain region when viewed from the top; and a gate electrode formed of metal silicide on the gate insulation film. In the semiconductor device, a gate length of upper part of the gate electrode is larger than a gate length of other part of the gate electrode.

In this structure, the gate length of the upper part of the gate electrode is larger than the gate length of other part of the gate electrode and, when a gate electrode of metal silicide is formed, a metal film can be deposited over a layer to be silicidized in a relatively simple manner. Thus, in the semiconductor device of the present invention, a gate electrode which is formed of uniform metal silicide and of which a resistance is reduced can be provided. As a result, a semiconductor device in which defective transistor characteristics and quality variations are suppressed can be realized.

In the above-described structure, the metal gate electrode, i.e., a gate electrode entirely formed of metal silicide is provided. Thus, compared to a known semiconductor device in which a silicide layer is provided on an upper surface of a gate electrode, a highly reliable semiconductor device in which reduction of current driving power is suppressed can be realized.

The semiconductor device of the present invention may further include: an interlevel insulation film formed so as to be located over the semiconductor substrate and at each side of the gate electrode; and a first sidewall film formed between a side surface of the gate electrode and the interlevel insulation film. In this case, the semiconductor device of the present invention may further include a second sidewall film formed between the first sidewall film and lower part of the side surface of the gate electrode.

In the above-described structure, the first sidewall film and the second sidewall film are provided at each side of the gate electrode and the gate electrode has an inverted convex shape in which a gate length of upper part thereof is larger than a gate length of lower part thereof. With this structure, when a gate electrode is formed, the second sidewall film is not formed on upper part of a side surface of the gate electrode. Thus, a metal film can be more uniformly formed on a layer to be silicidized, so that the gate electrode of uniform metal silicide can be obtained. As a result, a semiconductor device which includes a gate electrode with a sufficiently reduced resistance and in which defective transistor characteristics is suppressed can be realized.

It is preferable that the metal silicide contains at least one of titanium silicide, cobalt silicide, nickel silicide, tungsten silicide, tantalum silicide, hafnium silicide, zirconium silicide, molybdenum silicide and platinum silicide.

A first method for fabricating a semiconductor device according to the present invention includes the steps of: a) forming a gate insulation film, a gate electrode formation film and a first insulation film in this order from a bottom on a gate electrode formation region of a semiconductor substrate; b) implanting ions into the semiconductor substrate using the first insulation film as a mask to form a source region and a drain region; c) removing, after depositing a second insulation film over the semiconductor substrate, the second insulation film until an upper surface of the first insulation film is exposed; d) removing the first insulation film to form an opening portion which reaches the gate electrode formation film; e) forming the opening portion into an inverted tapered shape in which a width of an upper surface thereof in a gate length direction is larger than a width of other part thereof in the gate length direction; f) depositing a metal film over the semiconductor substrate to fill the opening portion with the metal film; and g) performing heat treatment to the semiconductor substrate to bring the metal film and the gate electrode formation film into reaction, thereby forming a gate electrode of metal silicide on the gate insulation film.

According to the method, in the step e), the opening portion can be processed into an inverted tapered shape to improve coverage of the metal film. Therefore, in the subsequent process step, the metal film can be deposited in the opening portion in a relatively uniform manner. Accordingly, during heat treatment in the step g), the metal film and the gate electrode formation film can be efficiently and evenly brought into reaction, so that a gate electrode of uniform metal silicide can be formed. As a result, with use of the first method for fabricating a semiconductor device according to the present invention, a semiconductor device which includes a gate electrode with a reduced resistance and in which defective transistor characteristics and quality variations are suppressed can be realized.

Moreover, with use of the first method for fabricating a semiconductor device according to the present invention, even when an aspect ratio of the opening portion formed in the step d) is increased, the opening portion is processed into an inverted tapered shape in the step e) and a uniform metal silicide layer can be formed. Accordingly, even when a gate length is reduced due to reduction in size of transistors, a silicide layer having a sufficient thickness can be formed. Therefore, a semiconductor device which includes a gate electrode with a reduced resistance and can be operated at high speed can be fabricated.

Furthermore, the gate electrode formed according to the above-described method has an inverted tapered shape in which a gate length of upper part thereof is larger than a gate length of lower part thereof. Thus, for example, when a contact is formed on the gate electrode, a region in which a contact can be formed is larger than that in the known semiconductor device including a gate electrode with a constant gate length. Accordingly, even when miniaturization of semiconductor devices is achieved, alignment of a mask used in forming a contact can be easily done and a contact can be formed on the gate electrode in a relatively simple manner.

It is preferable that a thickness of the first insulation film formed in the step a) is one third or more and one half or less of a sum of respective thicknesses of the gate insulation film, the gate electrode formation film and the first insulation film. In this case, the metal film which is necessary for sufficiently silicidizing the entire gate electrode formation region can be deposited and a gate electrode entirely formed of uniform metal silicide can be obtained.

It is preferable that the metal film contains at least one of titanium, cobalt, nickel, tungsten, tantalum, hafnium, zirconium, molybdenum and platinum.

A second method for fabricating a semiconductor device according to the present invention includes the steps of: a) forming a gate insulation film, a gate electrode formation film and a first insulation film in this order from a bottom on a gate electrode formation region of a semiconductor substrate; b) forming a first sidewall film over the semiconductor substrate and at sides of the gate electrode formation film and the first insulation film and a second sidewall film between the first sidewall film and each of the gate electrode formation film and a side surface of the first insulation film, the second sidewall film having different film quality from film quality of the first sidewall film; c) implanting ions into the semiconductor substrate using the first insulation film, the first sidewall film and the second sidewall film as a mask to form a source region and a drain region; d) removing, after depositing a second insulation film over the semiconductor substrate, the second insulation film until an upper surface of the first insulation film is exposed; e) removing the first insulation film and part of the second sidewall to form an opening portion which reaches the gate electrode formation film; f) depositing a metal film over the semiconductor substrate to fill the opening portion with the metal film; and g) performing heat treatment to the semiconductor substrate to bring the metal film and the gate electrode formation film into reaction, thereby forming a gate electrode of metal silicide on the gate insulation film.

According to the method, by removing part of the second sidewall film as well as the first insulation film, a width of the opening portion in the gate length direction can be increased by an amount corresponding to a width of the second sidewall film. Thus, compared to the first method for fabricating a semiconductor device according to the present invention, the metal film can be deposited more uniformly. Therefore, a gate electrode which is formed of uniform metal silicide and of which resistance is reduced can be formed.

### BRIEF DESCRIPTION OF THE DRAWINGS

FIGS. 1A through 1I are cross-sectional views illustrating respective steps for fabricating a semiconductor device according to a first embodiment of the present invention.

FIGS. 2A through 2I are cross-sectional views illustrating respective steps for fabricating a semiconductor device according to a second embodiment of the present invention.

FIGS. 3A through 3I are cross-sectional views illustrating respective steps for fabricating a semiconductor device according to a third embodiment of the present invention.

FIGS. 4A through 4J are cross-sectional views illustrating respective steps for fabricating a semiconductor device according to a fourth embodiment of the present invention.

FIGS. 5A through 5G are cross-sectional views illustrating respective steps for forming a silicide layer in a known semiconductor device.

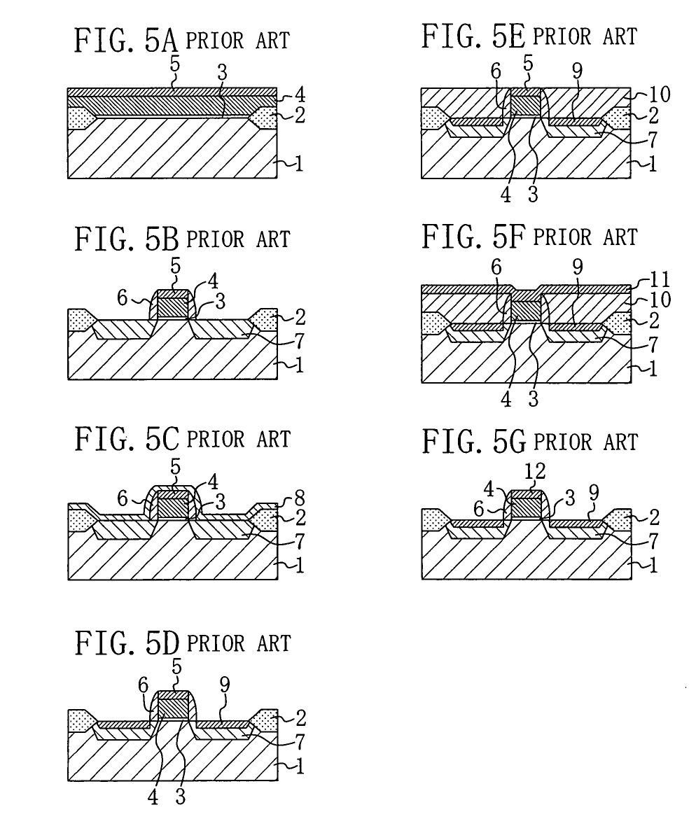

### DESCRIPTION OF THE PREFERRED EMBODIMENTS

### First Embodiment

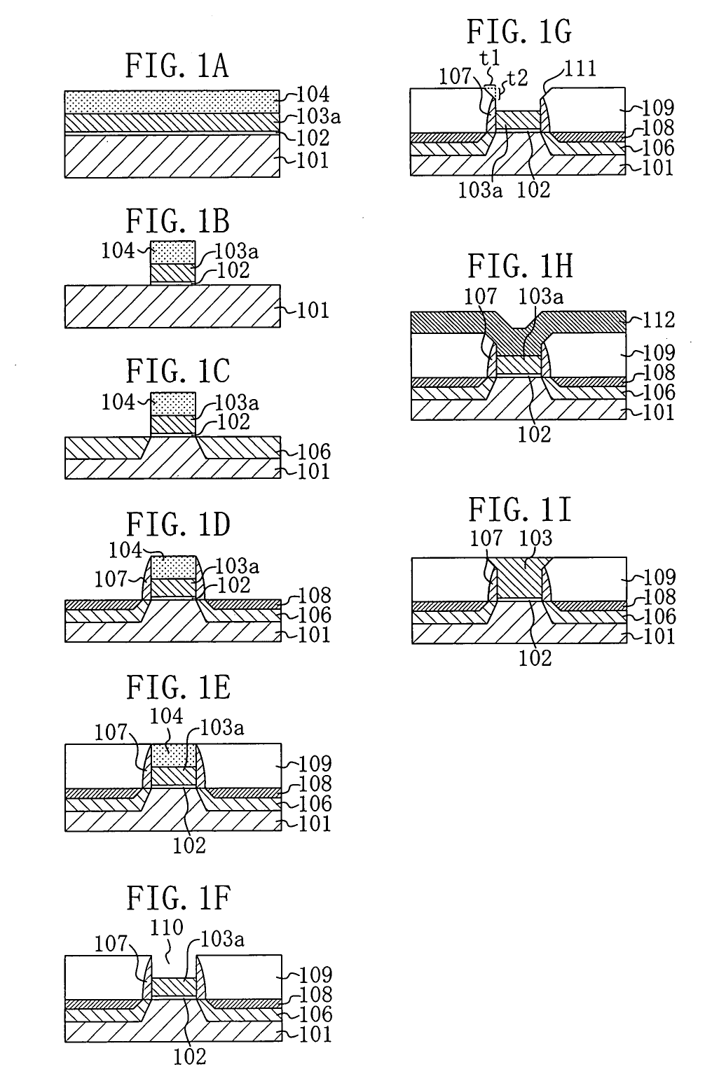

Hereafter, a semiconductor device according to a first embodiment of the present invention and a method for fabricating the semiconductor device will be described with reference to the accompanying drawings. FIGS. 1A through 1I are cross-sectional views illustrating respective steps for fabricating a semiconductor device according to the first embodiment of the present invention. First, a structure of the semiconductor device of this embodiment will be briefly described with reference to FIG. 1I.

As shown in FIG. 1I, the semiconductor device of this embodiment includes a semiconductor substrate 101 of silicon or the like, low concentration source/drain regions 106 and high concentration source/drain regions 108 each being formed in the semiconductor substrate 101, a gate insulation film 102 formed in part of the semiconductor substrate 101 located between the low concentration source/drain regions is 106 when viewed from the top, a gate electrode 103 formed of metal silicide on the gate insulation film 102, an interlevel insulation film 109 formed so as to be located above the semiconductor substrate 101 and at a side of the gate electrode 103, and a sidewall film 107 provided between the interlevel insulation film 109 and the gate electrode 103.

As a material for each of the gate insulation film 102, the interlevel insulation film 109 and the sidewall film 107, for example, a silicon oxide film is used.

In the semiconductor device of this embodiment, the gate electrode 103 is formed of metal silicide such as nickel silicide and the like. Furthermore, an upper portion of the gate electrode 103 has an inverted tapered shape of which a width in a gate length direction at an upper surface is larger than a width in the gate length direction in other part.

Since the semiconductor device of this embodiment includes the gate electrode 103 entirely formed of metal silicide, which is a metal gate electrode, reduction in current driving power can be suppressed in the semiconductor device of this embodiment, compared to a known semiconductor device in which a silicide layer is provided on an upper surface of a gate electrode. Therefore, a highly reliable semiconductor device can be achieved.

Next, a method for fabricating a semiconductor device according to this embodiment will be described with reference to FIGS. 1A through 1I.

First, as shown in FIG. 1A, for example, a gate insulation film 102 is formed of a silicon oxide film or the like on a semiconductor substrate 101 of, for example, silicon so as to have a thickness of 3 nm. Thereafter, with a temperature of the semiconductor substrate 101 set to be, for example, 610° C., a gate electrode formation film 103a of, for example, polycrystalline silicon is deposited over the gate insulation film 102 to a thickness of 80 nm. Subsequently, a first insulation film 104 of, for example, a silicon nitride film is deposited on the gate electrode formation film 103a to a thickness of 50 nm. In this process step, the thickness of the first insulation film 104 is preferably ⅓ or more and ½ or less of the sum of respective thicknesses of the gate insulation film 102, the gate electrode formation film 103a and the first insulation film 104.

Next, as shown in FIG. 1B, patterning is performed using lithography and dry etching so that parts of the first insulation film 104, the gate electrode formation film 103a and the gate insulation film 102 are left on a gate electrode formation region of the semiconductor substrate 101.

Next, as shown in FIG. 1C, using the first insulation film 104 as a mask, arsenic which is an n-type impurity is implanted into the semiconductor substrate 101 at a dose of 3×10¹⁴ ions/cm² and an implantation energy of 20 keV to form low concentration source/drain regions 106.

Subsequently, as shown in FIG. 1D, after depositing, for example, a silicon oxide film over the semiconductor substrate 101 to a thickness of 140 nm by CVD, the silicon oxide film is etched back by anisotropic etching to form a sidewall film 107 of a silicon oxide film on side surfaces of the gate insulation film 102, the gate electrode formation film 103a and the first insulation film 104. Thereafter, using the first insulation film 104 and the sidewall film 107 as a mask, arsenic which is an n-type impurity is ion implanted into the semiconductor substrate 101 at a dose of 4×10¹⁵ ions/cm² and an implantation energy of 50 keV to form high concentration source/drain regions 108.

Next, as shown in FIG. 1E, after depositing an interlevel insulating film 109 of, for example, a silicon oxide film over the semiconductor substrate 101 to a thickness of 700 nm by CVD, polishing is performed by CMP (Chemical Mechanical Polishing) until the first insulation film 104 is exposed. In this process step, for example, a platen rotation number of 100 rpm and a pressure of 4.0 psi (27.6 kPa) are used as conditions.

Next, as shown in FIG. 1F, the first insulation film 104 is removed by wet etching to form an opening portion 110 so that the opening portion 110 reaches the gate electrode formation film 103a. In this process step, using phosphorus acid as an etchant for wet etching, the process is performed, for example, at 150° C. Thus, a selection ratio of the first insulation film 104 to the gate electrode formation film 103a can be set to be 100 or larger, so that the first insulation film 104 can be selectively removed.

Next, as shown in FIG. 1G, upper portions of parts of the sidewall film 107 and the interlevel insulation film 109 facing the opening portion 110 are removed by sputtering to form the opening portion 110 into an inverted tapered shape 111. As for conditions for sputtering, using an inductive coupling dry etching apparatus, argon gas is supplied at a flow rate of 10 sccm (1.67×10⁻⁷ m³/s) and a pressure of 0.2 mTorr (26.7 mPa) and, with an RF power of an upper electrode set to be 300 W and an RF power of a lower electrode set to be 350 W, sputtering is performed for 40 seconds. If sputtering is performed under the above-described conditions, an amount (t1) of increase in a width of the opening portion 110 in the gate length direction is, for example, 20 nm per side and an amount (t2) of shoulder cut off is, for example, 30 nm. Moreover, in this process step, assuming that x denotes a distance from one upper edge of the opening portion 110 to the other upper edge thereof, y denotes the sum of widths of lower surfaces of sidewalls 107 provided on both side surfaces of the gate electrode formation film 103a and z denotes a width of the gate electrode formation film 103a in the gate length direction, it is preferable that (⅛y+z)<x<(y+z) holds. In this case, by ensuring a sufficient opening width, filling property for the opening portion 110 can be improved and also contact between contact holes in source/drain regions formed in the subsequent process step and the gate electrode 103 can be prevented.

Next, as shown in FIG. 1H, a metal film 112 of, for example, nickel is deposited over the semiconductor substrate 101 to a thickness of 30 nm by sputtering.

Subsequently, as shown in FIG. 1I, short time heat treatment (RTA) is performed within a temperature range from 550° C. to 600° C. to bring the gate electrode formation film 103a and nickel (the metal film 112) into reaction. Thus, the gate electrode 103 of nickel silicide having a thickness of, for example, 130 nm can be obtained. Thereafter, remaining unreacted nickel is selectively removed by wet etching using a liquid obtained by adding hydrogen peroxide solution to hydrochloric acid or sulfuric acid. Subsequently, short time heat treatment (RTA) is further performed within a temperature range from 750° C. to 800° C. to reduce a resistance of the gate electrode 103 of nickel silicide. Thereafter, a predetermined method is performed, so that a semiconductor device including a gate electrode of metal silicide according to this embodiment is completed.

The process conditions described in the above-described method for fabricating a semiconductor device are merely examples and process conditions are not limited thereto.

In accordance with the method for fabricating a semiconductor device according to this embodiment, in the process step shown in FIG. 1G, the opening portion 110 is formed into the inverted tapered shape 111, so that coverage of the metal film 112 can be improved and the metal film 112 can be deposited in the opening portion 110 in a relatively uniform manner in the subsequent step. Thus, during heat treatment, the metal film 112 and polycrystalline silicon (the gate electrode formation film 103a) can be effectively and evenly reacted with each other and the gate electrode 103 of uniform metal silicide can be formed. As a result, with the method for fabricating a semiconductor device according to this embodiment, a semiconductor device which includes a gate electrode with a reduced resistance and in which defective transistor characteristics and quality variations can be suppressed can be fabricated.

In accordance with the method for fabricating a semiconductor device according to this embodiment, even when an aspect ratio of an opening section formed in FIG. 1F is increased, a uniform metal silicide layer can be formed by forming the opening portion into an inverted tapered shape. Thus, even when an effective gate length is reduced due to reduction in transistor size, a silicide layer can be formed so as to have a sufficient thickness. Therefore, a semiconductor device which includes a gate electrode with a reduced resistance and can be performed at high speed can be fabricated. Herein, an “effective gate length” means a gate length of lower part of the gate electrode 103 which influences a channel length.

The gate electrode 103 formed according to the fabrication method of this embodiment has an inverted tapered shape in which a gate length of upper part thereof is larger than a gate length of the lower part thereof. Thus, for example, when a contact is formed on the gate electrode, a region in which a contact can be formed is larger than that in the known semiconductor device including a gate electrode with a constant gate length. Accordingly, even when miniaturization of semiconductor devices is achieved, alignment of a mask used in forming a contact can be easily done and a contact can be formed on the gate electrode in a relatively simple manner.

According to the fabrication method of this embodiment, the metal film preferably contains at least one of titanium, cobalt, nickel, tungsten, tantalum, hafnium, zirconium, molybdenum and platinum.

### Second Embodiment

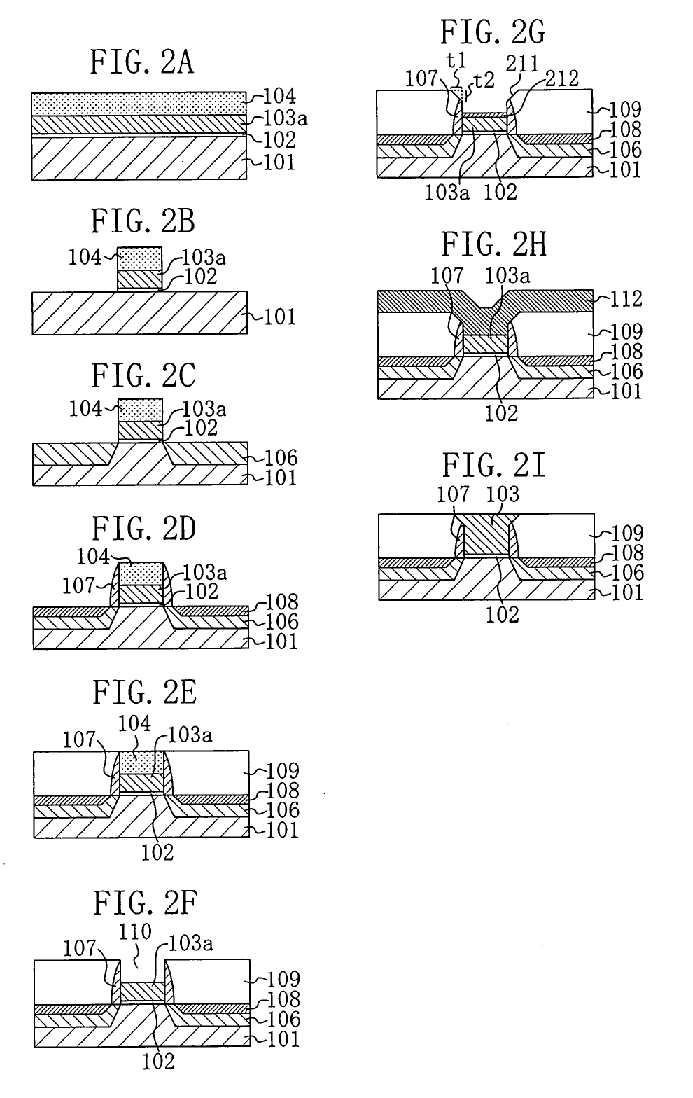

Hereafter, a method for fabricating a semiconductor device according to a second embodiment of the present invention will be described with reference to the accompanying drawings. A semiconductor device according to this embodiment has a similar structure to the structure of the semiconductor device of the first embodiment but part of the method for fabricating a semiconductor device according to this embodiment is different from the method for fabricating a semiconductor device according to the first embodiment. Therefore, in this embodiment, the structure of the semiconductor device will be omitted. FIGS. 2A through 2I are cross-sectional views illustrating respective steps for fabricating a semiconductor device according to the second embodiment of the present invention. Except for the step of FIG. 2G, process steps of the fabrication method of the second embodiment are the same as those of the fabrication method of the first embodiment and therefore will be briefly described.

First, as shown in FIGS. 2A and 2B, a gate insulation film 102, a gate electrode formation film 103a and a first insulation film 104 are formed in this order on a semiconductor substrate 101 and then patterning is performed so that parts of the gate insulation film 102, the gate electrode formation film 103a and the first insulation film 104 are left in a gate electrode formation region on the semiconductor substrate 101.

Subsequently, as shown in FIGS. 2C and 2D, using the first insulation film 104 as a mask, low concentration source/drain regions 106 are formed in the semiconductor substrate 101 and then a sidewall film 107 is formed on side surfaces of the gate insulation film 102, the gate electrode formation film 103a and the first insulation film 104.

Next, as shown in FIGS. 2E and 2F, using the first insulation film 104 and the sidewall film 107 as a mask, ion implantation is performed under predetermined conditions to form high concentration source/drain regions 108. Subsequently, after depositing an interlevel insulation film 109 over the semiconductor substrate 101, polishing is performed by CMP until the first insulation film 104 is exposed. Thereafter, the first insulation film 104 is removed and an opening portion 110 is formed.

Subsequently, as shown in FIG. 2G, upper potions of part of the sidewall film 107 facing the opening portion 110 and part of the interlevel insulation film 109 located in the vicinity of the opening portion 110 are removed by reactive ion etching to form the opening portion 110 into an inverted tapered shape 211. As for conditions for reactive ion etching performed in this process step, using a two-frequency reactive ion etching apparatus, oxygen gas is supplied at a flow rate of 400 sccm (6.68×10⁻⁶ m³/s) and a pressure of 3 Pa and, with a power of a source electrode set to be 900 W and a power of a bias electrode set to be 600 W, reactive ion etching is performed for 60 seconds, thereby forming the opening portion 110 into the inverted tapered shape 211. If reactive ion etching is performed under the above-described conditions, an amount (t1) of increase in a width of the opening portion 110 in the gate length direction is increased, for example, by 20 nm per side and an amount (t2) of shoulder cut off is, for example, 20 nm. Moreover, in this process step, assuming that x denotes a distance from one upper edge of the opening portion 110 to the other upper edge thereof, y denotes the sum of widths of lower surfaces of sidewalls 107 provided on both side surfaces of the gate electrode formation film 103a and z denotes a width of the gate electrode formation film 103a in the gate length direction, it is preferable that (⅛y+z)<x<(y+z) holds.

When the above-described reactive ion etching using oxygen is performed, a surface of polycrystalline silicon (the gate electrode formation film 103a) is oxidized and a product 212 of, for example, silicon oxide is formed. Accordingly, in this process step, after performing reactive ion etching, hydrofluoric acid cleaning is performed to remove the product 212 of silicon oxide. At this time, an impurity such as nitrogen remaining on the gate electrode formation film 103a is removed with the product 212.

Next, as shown in FIGS. 2H and 2I, a metal film 112 of, for example, nickel is deposited over the semiconductor substrate 101. Subsequently, short time heat treatment is performed to bring the gate electrode formation film 103a and nickel (the metal film 112) into reaction, thereby forming a gate electrode 103 of nickel silicide on the gate insulation film 102. Thereafter, remaining unreacted nickel is selectively removed by wet etching. Subsequently, short time heat treatment is performed to reduce a resistance of the gate electrode 103 of nickel silicide. Thereafter, a predetermined method is performed, so that a semiconductor device including the gate electrode 103 of a metal silicide layer according to this embodiment is completed.

The process conditions described in the above-described method for fabricating a semiconductor device are merely examples and process conditions are not limited thereto.

In accordance with the method for fabricating a semiconductor device according to this embodiment, in the same manner as in the first embodiment, in the process step of FIG. 2G, the opening portion 110 is formed into the inverted tapered shape 211, so that coverage of the metal film 112 can be improved and the metal film 112 can be deposited in the opening portion 110 in a relatively uniform manner in the subsequent step. Thus, during heat treatment, the metal film 112 and polycrystalline silicon (the gate electrode formation film 103a) can be effectively and evenly reacted with each other. Therefore, even when an effective gate length is reduced, the gate electrode 103 of uniform metal silicide can be formed. As a result, by the method for fabricating a semiconductor device according to this embodiment, a semiconductor device which includes a gate electrode with a reduced resistance and in which defective transistor characteristics and quality variations are suppressed can be fabricated.

In accordance with the method for fabricating a semiconductor device according to this embodiment, the process step of FIG. 2G includes a step of removing, after forming the opening portion 110 into the inverted tapered shape 211, the product 212 formed by reactive ion etching. Since the process step includes the step of removing the product 212, an impurity such as nitrogen remaining on a surface of the gate electrode formation film 103a can be removed as well. Therefore, interruption of reaction between the metal film and polycrystalline silicon by the impurity can be suppressed and a gate electrode of more uniform metal silicide can be formed.

### Third Embodiment

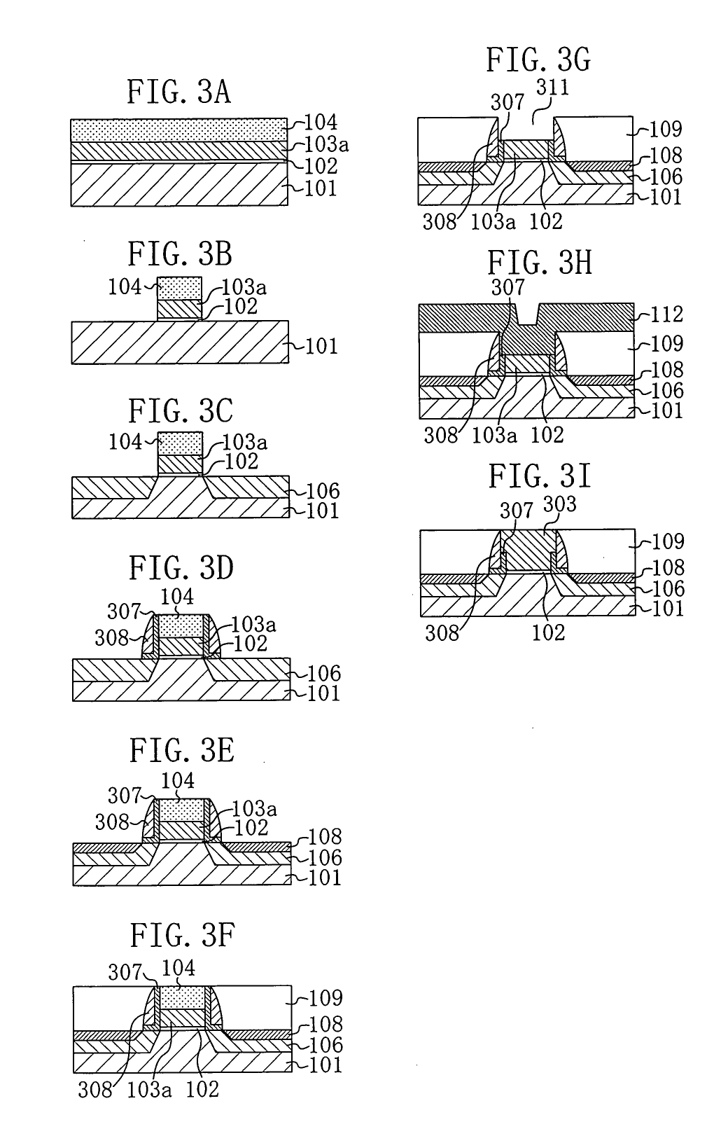

Hereafter, a semiconductor device according to a third embodiment of the present invention and a method for fabricating the semiconductor device will be described with reference to the accompanying drawings. FIGS. 3A through 3I are cross-sectional views illustrating respective steps for fabricating a semiconductor device according to the third embodiment of the present invention. First, a structure of the semiconductor device of this embodiment will be described with reference to FIG. 3I.

As shown in FIG. 3I, the semiconductor device of this embodiment includes a semiconductor substrate 101 of silicon or the like, low concentration source/drain regions 106 and high concentration source/drain regions 108 each being formed in the semiconductor substrate 101, a gate insulation film 102 formed in part of the semiconductor substrate 101 located between the low concentration source/drain regions 106 when viewed from the top, a gate electrode 303 formed of metal silicide on the gate insulation film 102, a first sidewall film 308 provided so as to be located above the semiconductor substrate 101 and at a side of the gate electrode 303, a second sidewall film 307 provided between the first sidewall film 308 and a side surface of lower part of the gate electrode 303 and an interlevel insulation film 109 formed so as to be located above the semiconductor substrate 101 and at a side of the first sidewall film 308.

As materials for the first sidewall film 308 and the second sidewall film 307, for example, a silicon oxide film and a silicon nitride film are used, respectively. As a material for each of the gate insulation film 102 and the interlevel insulation film 109, for example, a silicon oxide film is used.

In the semiconductor device of this embodiment, the gate electrode 303 is formed of, for example, metal silicide such as nickel silicide. Furthermore, the gate electrode 303 has an inverted convex portion in which a width of upper part thereof is larger than a width of the lower part thereof.

Next, a method for fabricating a semiconductor device according to this embodiment will be described with reference to FIGS. 3A through 3I. The process steps shown in FIGS. 3A through 3C are the same as those of the first embodiment and therefore will be briefly described in this embodiment.

First, as shown in FIGS. 3A through 3C, a gate insulation film 102, a gate electrode formation film 103a and a first insulation film 104 are formed in this order over a semiconductor substrate 101 and then patterning is performed so that parts of the gate insulation film 102, the gate electrode formation film 103a and the first insulation film 104 are left in a gate electrode formation region on the semiconductor substrate 101. Subsequently, using the first insulation film 104 as a mask, low concentration source/drain regions 106 are formed in the semiconductor substrate 101.

Next, as shown in FIG. 3D, for example, a silicon oxide film and a silicon nitride film are deposited in this order over the semiconductor substrate 101 by CVD. Thereafter, the silicon nitride film and the silicon oxide film are etched back by anisotropic etching, thereby forming a sidewall film 308 provided so as to be located above the semiconductor substrate 101 and at a side of the gate electrode formation film 103a and the first insulation film 104 and a second sidewall film 307 provided between the first sidewall film 308 and each of side surfaces of the gate electrode formation film 103a and the first insulation film 104.

Next, as shown in FIGS. 3E and 3F, using the first insulation film 104, the first sidewall film 308 and the second sidewall film 307 as a mask, ion implantation is performed under predetermined conditions, thereby forming high concentration source/drain regions 108. Thereafter, after depositing an interlevel insulation film 109 over the semiconductor substrate 101, polishing is performed by CMP until the first insulation film 104 is exposed.

Next, as shown in FIG. 3G, the first insulation film 104 and upper part of the second sidewall film 307 are removed at the same time by wet etching to form an opening portion 311 so that the opening portion 311 reaches the gate electrode formation film 103a. In this process step, using phosphorus acid as an etchant for wet etching, the process is performed, for example, at 150° C. Thus, a selection ratio of each of the first insulation film 104 of a nitride silicon film and the second sidewall film 307 to the gate electrode formation film 103a can be set to be 100 or larger, so that part of each of the first insulation film 104 and the second sidewall film 307 can be selectively removed.

Next, as shown in FIGS. 3H and 3I, a metal film 112 of, for example, nickel is deposited over the semiconductor substrate 101. Subsequently, short time heat treatment is performed to bring the gate electrode formation film 103a and nickel (the metal film 112) into reaction, thereby forming a gate electrode 303 of nickel silicide on the gate insulation film 102. Thereafter, remaining unreacted nickel is selectively removed by wet etching. Subsequently, short time heat treatment is performed to reduce a resistance of the gate electrode 303 of nickel silicide. Thereafter, a predetermined method is performed, so that a semiconductor device including the gate electrode 303 of a metal silicide layer according to this embodiment is completed.

The process conditions described in the above-described method for fabricating a semiconductor device are merely examples and process conditions are not limited thereto.

In accordance with the method for fabricating a semiconductor device according to this embodiment, in the process step of FIG. 3G, parts of the first insulation film 104 and the second sidewall film 307 are removed, so that a width of the opening portion 311 can be increased by an amount correspond to a width of the second sidewall film 307. Thus, compared to the case where only the first insulation film 104 is removed to form an opening portion, the metal film 112 can be deposited more uniformly in the opening portion 311. Accordingly, during heat treatment, the metal film 112 and polycrystalline silicon (the gate electrode formation film 103a) can be effectively and evenly reacted with each other. Therefore, even when an effective gate length is reduced, the gate electrode 303 of uniform metal silicide can be formed. As a result, with the method for fabricating a semiconductor device according to this embodiment, a semiconductor device which includes a gate electrode with a reduced resistance and in which defective transistor characteristics and quality variations can be suppressed can be fabricated.

The gate length on an upper surface of the gate electrode 303 formed by the fabrication method of this embodiment is smaller than that of the gate electrode 103 in the first embodiment. Thus, for example, when contacts are formed on the high concentration source/drain regions 108, a region in which contacts can be formed is larger than that in the semiconductor device of the first embodiment. As a result, even when miniaturization of semiconductor devices is achieved, alignment of a mask used in forming contacts can be easily done and contacts can be formed on the source/drain regions in a relatively simple manner.

The method for fabricating a semiconductor device according to this embodiment may include, after the step of FIG. 3G and before the step of FIG. 3H, the step of removing upper portions of parts of the interlevel insulation film 109 and the first sidewall film 308 facing the opening portion 311. In this case, the opening portion 311 can be processed into an inverted tapered shape in which a width of upper surface thereof in the gate length direction is larger than a width of other part thereof in the gate length direction. Thus, coverage of the metal film 112 can be further improved in the subsequent process step and the gate electrode 303 of more uniform metal silicide can be fabricated.

In the fabrication method of this embodiment, it is preferable that the first insulation film 104 and the second sidewall film 307 are formed of the same material. Thus, in the process step of FIG. 3G, the first insulation film 104 and the second sidewall film 307 can be removed in a relatively simple manner by etching.

### Fourth Embodiment

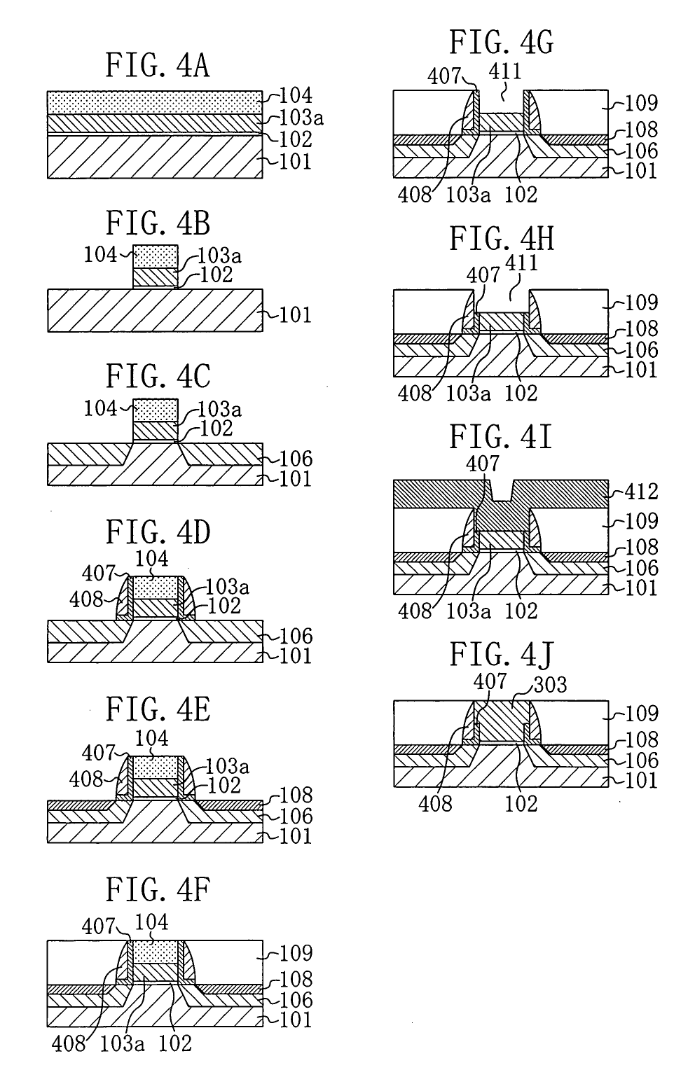

Hereafter, a method for fabricating a semiconductor device according to a fourth embodiment of the present invention with reference to the accompanying drawings. The semiconductor device of this embodiment includes a second sidewall film formed of the same material as that of a first sidewall film. Other part than this has the same structure as the semiconductor device of the third embodiment. Therefore, the description of the structure of the semiconductor device will be omitted. Part of the method for fabricating the semiconductor device according to this embodiment is different from the method for fabricating a semiconductor device according to the third embodiment of the present invention. FIGS. 4A through 4J are cross-sectional views illustrating respective steps for fabricating a semiconductor device according to a fourth embodiment of the present invention. Process steps of FIGS. 4A through 4C are the same as those of the fabrication method of the first embodiment and therefore will be briefly described.

First, as shown in FIGS. 4A through 4C, a gate insulation film 102, a gate electrode formation film 103a and a first insulation film 104 are formed in this order over a semiconductor substrate 101 and then patterning is performed so that parts of the gate insulation film 102, the gate electrode formation film 103a and the first insulation film 104 are left in a gate electrode formation region on the semiconductor substrate 101. Subsequently, using the first insulation film 104 as a mask, low concentration source/drain regions 106 are formed in the semiconductor substrate 101.

Next, as shown in FIG. 4D, for example, a silicon oxide film (first silicon oxide film) is formed over the semiconductor substrate 101 by CVD using ozone gas and TEOS (tetraethoxysilane) gas within a temperature range from 300° C. to 400° C. Thereafter, a second silicon oxide film is formed over the first silicon oxide film using oxide gas and TEOS (tetraethoxysilane) gas within a temperature range from 700° C. to 900° C. Subsequently, the first silicon oxide film and the second silicon oxide film are etched back by anisotropic etching, thereby forming a first sidewall film 408 provided so as to be located above the semiconductor substrate 101 and at sides of the gate electrode formation film 103a and the first insulation film 104 and a second sidewall film 407 provided between the first sidewall film 408 and each of side surfaces of the gate electrode formation film 103a and the first insulation film 104.

Next, as shown in FIGS. 4E and 4F, using the first insulation film 104, the first sidewall film 408 and the second sidewall film 407 as a mask, ion implantation is performed under predetermined conditions, thereby forming high concentration source/drain regions 108. Thereafter, after depositing an interlevel insulation film 109 over the semiconductor substrate 101, polishing is performed by CMP until the first insulation film 104 is exposed.

Next, as shown in FIG. 4G, the first insulation film 104 is removed by wet etching. In this process step, using phosphorus acid as an etchant for wet etching, the process is performed, for example, at 150° C. Thus, a selection ratio of the first insulation film 104 of a nitride silicon film to the gate electrode formation film 103a can be set to be 100 or larger, so that part of each of the first insulation film 104 can be selectively removed.

Subsequently, as shown in FIG. 4H, upper part of the second sidewall film 407 is removed by wet etching, for example, until an upper surface of the second sidewall film 407 becomes the same height as that of an upper surface of the gate electrode formation film 103a. In this process step, for example, a solution obtained by diluting hydrofluoric acid (100%) by a factor of 500 in pure water is used as an etchant for wet etching. Thus, a selective ratio of the second sidewall film 307 to the first sidewall film 308 can be set to be 3 or larger, so that only the second sidewall film 307 can be selectively removed. As a material for the second sidewall film 307, an NSG (non-doped silicate glass) film is preferably used. In this process step, the second sidewall film 407 is etched so that the upper surface of the second sidewall film 407 becomes the same height as that of the upper surface of the gate electrode formation film 103a. However, the height of the second sidewall film 407 is not limited thereto but the upper surface of the second sidewall film 407 may be higher or lower than the upper surface of the gate electrode formation film 103a.

Next, as shown in FIGS. 4I and 4J, a metal film 112 of, for example, nickel is deposited over the semiconductor substrate 101. Subsequently, short time heat treatment is performed to bring the gate electrode formation film 103a and nickel (the metal film 412) into reaction, thereby forming a gate electrode 303 of nickel silicide on the gate insulation film 102. Thereafter, remaining unreacted nickel is selectively removed by wet etching. Subsequently, short time heat treatment is performed to reduce a resistance of the gate electrode 303 of nickel silicide. Thereafter, a predetermined method is performed, so that a semiconductor device including the gate electrode 303 of a metal silicide layer according to this embodiment is completed.

The process conditions described in the above-described method for fabricating a semiconductor device are merely examples and process conditions are not limited thereto.

In accordance with the method for fabricating a semiconductor device according to this embodiment, after removing the first insulation film 104 in the process step of FIG. 4G, in the process step of FIG. 4H, the upper part of the second sidewall film 407 can be also removed, so that the width of the opening portion 411 can be increased by an amount corresponding to the thickness of the second sidewall film 407. Thus, the metal film 412 can be more evenly deposited in the opening portion 411. Therefore, even when an effective gate length is reduced, during heat treatment, the metal film 412 and polycrystalline silicon (the gate electrode formation film 103a) can be effectively and evenly reacted with each other to form the gate electrode 303 of uniform metal silicide. As a result, with the method for fabricating a semiconductor device according to this embodiment, a semiconductor device which includes a gate electrode with a reduced resistance and in which defective transistor characteristics and quality variations can be suppressed can be fabricated.

In accordance with the method for fabricating a semiconductor device according to this embodiment, in the process step of FIG. 4D, the first sidewall film 408 is preferably formed at a higher temperature than the second sidewall film 407. In this case, the first sidewall film 408 and the second sidewall film 407 are formed to have different film qualities. Therefore, with predetermined etching conditions set in the process steps of FIG. 4H, only the second sidewall film 407 can be selectively etched.

As has been described, a semiconductor device according to the present invention and a method for fabricating the semiconductor device are useful in miniaturization of semiconductor devices including a gate electrode with a silicide layer.

What is claimed is:

1. A semiconductor device comprising:
a semiconductor substrate;
a source region and a drain region each being formed in the semiconductor substrate;
a gate insulation film formed on part of the semiconductor substrate located between the source region and the drain region when viewed from the top; and
a gate electrode formed of metal silicide on the gate insulation film,
wherein a gate length of upper part of the gate electrode is larger than a gate length of other part of the gate electrode.

2. The semiconductor device of claim 1, wherein the upper part of the gate electrode has an inverted tapered shape.

3. The semiconductor device of claim 1, further comprising:
an interlevel insulation film formed so as to be located over the semiconductor substrate and at each side of the gate electrode; and
a first sidewall film formed between a side surface of the gate electrode and the interlevel insulation film.

4. The semiconductor device of claim 3, further comprising a second sidewall film formed so as to extend between the first sidewall film and lower part of the side surface of the gate electrode and between the semiconductor substrate and the first sidewall film.

5. The semiconductor device of claim 1, wherein the metal silicide contains at least one of titanium silicide, cobalt silicide, nickel silicide, tungsten silicide, tantalum silicide, hafnium silicide, zirconium silicide, molybdenum silicide and platinum silicide.

6. A method for fabricating a semiconductor device, the method comprising the steps of:
a) forming a gate insulation film, a gate electrode formation film and a first insulation film in this order from a bottom on a gate electrode formation region of a semiconductor substrate;
b) implanting ions into the semiconductor substrate using the first insulation film as a mask to form a source region and a drain region;
c) removing, after depositing a second insulation film over the semiconductor substrate, the second insulation film until an upper surface of the first insulation film is exposed;
d) removing the first insulation film to form an opening portion which reaches the gate electrode formation film;
e) forming the opening portion into an inverted tapered shape in which a width of an upper surface thereof in a gate length direction is larger than a width of other part thereof in the gate length direction;
f) depositing a metal film over the semiconductor substrate to fill the opening portion with the metal film; and
g) performing heat treatment to the semiconductor substrate to bring the metal film and the gate electrode formation film into reaction, thereby forming a gate electrode of metal silicide on the gate insulation film.

7. The method of claim 6, wherein in the step of e), the opening portion is processed into an inverted tapered shape by sputtering.

8. The method of claim 6, wherein in the step e), the opening portion is processed into an inverted tapered shape by reactive ion etching using oxygen gas.

9. The method of claim 8, wherein the step e) includes, after forming the opening portion into an inverted tapered shape, the step of removing an impurity formed on the gate electrode formation film.

10. The method of claim 6 further includes, after the step a), the step h) of forming a sidewall film on side surfaces of the gate electrode formation film and the first insulation film,
wherein in the step b), the source region and the drain region are formed using the sidewall film and the first insulation film as a mask, and in the step e), upper portions of part of the second insulation film located in the vicinity of the opening portion and part of the sidewall film facing the opening portion are removed.

11. The method of claim 6, wherein a thickness of the first insulation film formed in the step a) is one third or more and one half or less of a sum of respective thicknesses of the gate insulation film, the gate electrode formation film and the first insulation film.

12. The method of claim 6, wherein the metal film contains at least one of titanium, cobalt, nickel, tungsten, tantalum, hafnium, zirconium, molybdenum and platinum.

13. A method for fabricating a semiconductor device, the method comprising the steps of:
a) forming a gate insulation film, a gate electrode formation film and a first insulation film in this order from a bottom on a gate electrode formation region of a semiconductor substrate;
b) forming a first sidewall film over the semiconductor substrate and at sides of the gate electrode formation film and the first insulation film and a second sidewall film between the first sidewall film and each of the gate electrode formation film and a side surface of the first insulation film, the second sidewall film having different film quality from film quality of the first sidewall film;
c) implanting ions into the semiconductor substrate using the first insulation film, the first sidewall film and the second sidewall film as a mask to form a source region and a drain region;
d) removing, after depositing a second insulation film over the semiconductor substrate, the second insulation film until an upper surface of the first insulation film is exposed;
e) removing the first insulation film and part of the second sidewall to form an opening portion which reaches the gate electrode formation film;
f) depositing a metal film over the semiconductor substrate to fill the opening portion with the metal film; and
g) performing heat treatment to the semiconductor substrate to bring the metal film and the gate electrode formation film into reaction, thereby forming a gate electrode of metal silicide on the gate insulation film.

14. The method of claim 13, further comprising, after the step e) and before the step f), removing an upper portion of part of the second insulation film located in the vicinity of the opening and an upper portion of part of the first sidewall film facing the opening portion to form the opening portion into an inverted tapered shape in which a width of an upper surface thereof in a gate length direction is larger than a width of other part thereof in the gate length direction.

15. The method of claim 13, wherein in the step e), the first insulation film and part of the sidewall film are removed at the same time.

16. The method of claim 15, wherein the first insulation film and the second sidewall film are formed of the same material.

17. The method of claim 13, wherein in the step b), the first sidewall film is formed at a higher temperature than the second sidewall film.

18. The method of claim 17, wherein in the step e), after removing the first insulation film, part of the second sidewall film is removed.

19. The method of claim 18, wherein in the step e), part of the second sidewall film is removed by etching using hydrofluoric acid, and
a selection ratio of the second sidewall film to the first sidewall film is 2 or larger.

20. The method of claim 19, wherein the second sidewall film is formed of an NSG film.

21. The method of claim 13, wherein a thickness of the first insulation film formed in the step a) is one third or more and one half or less of a sum of respective thicknesses of the gate insulation film, the gate electrode formation film and the first insulation film.

22. The method of claim 13, wherein the metal film contains at least one of titanium, cobalt, nickel, tungsten, tantalum, hafnium, zirconium, molybdenum and platinum.
